(19) United States
(12) Patent Application Publication
(10) Pub. No.: US 2007/0223193 A1
(43) Pub. Date: Sep. 27, 2007

(54) Transport System

(76) Inventor: Brian A. Hamman, Krugerville, TX (US)

Correspondence Address: Arthur W. Fisher;Patent Dominion Partnership, LP, 6103 Twin Oaks Circle, Dallas, TX, 75240, US

(21) Appl. No.: 11/386,900

(22) Filed: Mar. 23, 2006

(51) Int. Cl. H05K 7/20

(52) U.S. Cl. 361/689

(57) ABSTRACT

A cooling system with one or more coolant regulators is presented. A number of embodiments are presented. The coolant regulators maintain consistent coolant pressure and/or volume regardless of the number of heat-generating components being cooled and such that the consistent coolant pressure and/or volume is maintained while heat generating components are added to or removed from the electronic system while the electronic system remains on-line. One embodiment of the present invention is depicted for large, rack mountable electronic systems such as servers.

### CROSS REFERENCE TO RELATED APPLICATIONS

Reference is made to pending U.S. patent application Ser. No. 10/688,587 filed Oct. 18, 2003 for a detailed description of cooling systems and various heat transfer units and heat exchangers and their operation. Reference is also made to pending U.S. patent application Ser. No. 11/319,942 filed Dec. 29, 2005 for a detailed description of connector or socket heat transfer units; to pending U.S. patent application Ser. No. 11/336,304 filed Jan. 23, 2006 for a detailed description of leakage or spillage systems and sensors; to pending U.S. patent application Ser. No. 11/361,943 filed Feb. 27, 2006 for a detailed description of quick connectors for cooling systems; and to pending U.S. patent application Ser. No. 11/371,502 filed Mar. 10, 2006 for a detailed description of mounting systems for heat exchange units.

### BACKGROUND OF THE INVENTION

### Description of the Related Art

At the heart of data processing and telecommunication devices are processors and other heat-generating components which are becoming increasingly more powerful and generating increasing amounts of heat. As a result, more powerful cooling systems are required to prevent these components from thermal overload and resulting system malfunctions or slowdowns.

Traditional cooling approaches such as heat sinks and heat pipes are unable to practically keep up with this growing heat problem. As these components become increasingly more powerful, the size and weight of air-cooled solutions become more problematic as well. In smaller housings or rack mounted systems, the space required for air-cooled solutions becomes unacceptable. Cooling systems which use a liquid or gas to cool these heat generating components are becoming increasingly needed and more viable. These systems utilize heat transfer units thermally coupled to the heat generating components for absorbing or extracting heat from the heat generating components into a coolant flowing there through. The coolant, now heated, is directed to a heat exchanger where heat is dissipated from the coolant, creating cooled coolant and returned to the heat transfer unit to repeat the cycle.

The heat transfer units typically comprise a housing with a cavity there through for the coolant to flow through. The contact surface (with the heat generating components) must have excellent thermal transfer capability and a wide variety of materials can be used such as copper.

Many of the heat generating components of today and high powered microprocessors, in particular, are connected into the electronic system in which they will be used by means of a socket or connector. The socket is often soldered into a motherboard and has receptacles for receiving the pins of the component and allows for easy insertion and extraction into and out of the motherboard. The component then is not subjected to any mishaps that may incur during soldering or whatever insertion method is used. Such a socket or connector which is also a heat transfer unit is particularly desirable for systems requiring easy assembly of the cooling system.

For today's more complex systems, including, but not limited to, servers and other rack mounting data processing and telecommunication systems, the system is capable of having a different number of circuit boards with heat generating components such as, but not limited to, microprocessors connected to the system at any one time. Moreover, these circuit boards must be capable of being connected or disconnected at any time and while the server system or main system is running. Most, if not all, of these circuit boards will have one or more heat generating components requiring cooling by a heat transfer unit. Consequently, the volume and pressure of the coolant being used (and to be cooled by one or more heat exchange units) can change.

Thus, there is a need in the art for a method and apparatus for a cost-efficient, seamless method of regulating coolant pressure for systems having varying, at any one time, numbers of heat generating components to be cooled.

### SUMMARY OF THE INVENTION

A method and apparatus for a cooling system having a coolant for cooling one or more heat-generating components in an electronic system comprising one or more heat transfer units thermally coupled to one or more heat-generating components and having the coolant circulating there through for transferring heat from the heat-generating components to the coolant; and one or more coolant regulators wherein the regulator maintains consistent coolant pressure and/or volume of coolant to the heat transfer units regardless of how many heat-generating components are connected to the electronic system.

The method and apparatus for a cooling system as described above wherein the coolant regulators maintain consistent coolant pressure and/or volume before and after heat generating components are added to or removed from the electronic system.

The method and apparatus for a cooling system as described above further comprising one or more heat exchange units for receiving heated coolant at an inlet and for cooling said coolant to provide cooled coolant at an outlet; a variable number of heat transfer units thermally coupled to the one or more heat-generating components, the heat transfer units receiving cooled coolant at an inlet thereof from a heat exchange unit, transferring heat to the cooled coolant from one or more heat-generating components thermally coupled thereto and creating heated coolant and directing the heated coolant from an outlet thereof to a heat exchange unit for cooling the heated coolant; one or more transport means coupled to the heat transfer units and the heat exchange units for transporting cooled coolant from the heat exchange units to the heat transfer units and for transporting heated coolant from the heat transfer units to the heat exchange units; and wherein the coolant regulators are coupled to the transport means.

The method and apparatus for a cooling system as described above wherein one or more heat transfer units have an inlet positioned below an outlet for enhancing convective circulation of the coolant.

The method and apparatus for a cooling system as described above wherein one or more heat exchange units have an inlet positioned above an outlet for enhancing convective circulation of the coolant.

The method and apparatus for a cooling system as described above wherein the one or more coolant regulators are configured to allow maximum coolant volume to flow in the cooling system when power to the electronic system is disabled thereby enhancing convective circulation of the coolant after power shutdown.

The method and apparatus for a cooling system as described above wherein one or more heat transfer units are disposed on an interconnect means, said interconnect means further comprising one or more inserts or receptacles of one or more quick connectors and disposed such that one or more inserts or receptacles engage with a mating receptacle or insert, respectively, when the interconnect means is connected to the electronic system thereby enabling coolant communication to the heat transfer units and disengage when the interconnect means is disconnected from the electronic system thereby disabling coolant communication to the heat transfer units; heat transfer unit transport means for coupling the inlets and the outlets of the heat transfer units to the inserts or receptacles disposed on the interconnect means, and guide means coupled to the housing of the electronic system for insertion of the interconnect means there in for connecting and disconnecting the interconnect means to and from the electronic system.

The method and apparatus for a cooling system as described above further comprising one or more electrical connectors or receptacles disposed on the interconnect means for connecting with a mating receptacle or connector for enabling electrical power to the interconnect means when the interconnect means circuit card is connected to the electronic system and disabling electrical power when the interconnect means is disconnected from the electronic system.

The method and apparatus for a cooling system as described above further comprising sensing means coupled to an interconnect means for enabling electrical power to one or more heat exchange units when interconnect means is connected to the electronic system.

The method and apparatus for a cooling system as described above wherein one or more heat exchange units are disposed on an interconnect means, said interconnect means further comprising one or more inserts or receptacles of one or more quick connectors and disposed such that one or more inserts or receptacles engage with a mating receptacle or insert, respectively, when the interconnect means is connected to the electronic system thereby enabling coolant communication to the heat exchange units and disengage when the interconnect means is disconnected from the electronic system thereby disabling coolant communication to the heat exchange units; heat exchange unit transport means for coupling the inlets and the outlets of the heat exchange units to the inserts or receptacles disposed on the interconnect means, and guide means coupled to the housing of the electronic system for insertion of the interconnect means there in for connecting and disconnecting the interconnect means to and from the cooling system.

The method and apparatus for a cooling system as described above wherein the interconnect means is a board.

The method and apparatus for a cooling system as described above further comprising one or more electrical connectors or receptacles disposed on the interconnect means for connecting with a mating receptacle or connector for enabling electrical power to the heat exchange units when the interconnect means is connected to the electronic system and disabling electrical power when the interconnect means is disconnected from the electronic system.

The method and apparatus for a cooling system as described above further comprising sensing means coupled to the electrical connectors or receptacles and responsive to the presence of one or heat transfer units in coolant communication with one or more heat exchange units for enabling electrical power to such heat exchange units when one or more heat transfer units are in coolant communication with such heat exchange units and disabling electrical power to such heat exchange unit when no heat transfer units are in coolant communication with such heat exchange units.

The method and apparatus for a cooling system as described above wherein one or more coolant regulators are disposed on the interconnect means and coupled to one or more heat exchange units.

The method and apparatus for a cooling system as described above wherein one or more coolant regulators are disposed on an interconnect means, said interconnect means further comprising one or more inserts or receptacles of one or more quick connectors and disposed such that one or more inserts or receptacles engage with a mating receptacle or insert, respectively, when the interconnect means is connected to the electronic system thereby enabling coolant communication to the coolant regulators and disengage when the interconnect means is disconnected from the electronic system thereby disabling coolant communication to the coolant regulators; coolant regulator transport means for coupling the inlets and the outlets of the coolant regulators to the inserts or receptacles disposed on the interconnect means, and guide means coupled to the housing of the electronic system for insertion of the interconnect means there in for connecting and disconnecting the interconnect means to and from the cooling system.

The method and apparatus for a cooling system as described above wherein the coolant regulator comprises a housing having a coolant inlet and a coolant outlet; a movable pressure and/or volume sensing means responsive to the pressure and/or volume of the coolant; a flow control means coupled to the movable pressure sensing means for increasing or decreasing the pressure and/or volume of coolant; and coolant return means for transporting some of the coolant flowing through the coolant regulator back to the housing such that the movable pressure sensing means responds to increases in coolant pressure and/or volume.

The method and apparatus for a cooling system as described above wherein the movable pressure and/or volume sensing means is adjusted to maintain a relatively constant coolant pressure and/or volume of coolant to the heat transfer units.

### BRIEF DESCRIPTION OF THE DRAWINGS

FIG. 1 depicts a schematic of cooling system having a heat exchange unit, a plurality of heat transfer units and a coolant regulator.

FIG. 2 depicts a coolant regulator.

FIG. 3A depicts a circuit board with heat transfer units, inserts of quick connector assemblies and an electrical connector for easy connection to an electronic system, such as a rack mounted, server system.

FIG. 3B depicts a card having a plurality of heat exchange units and coolant regulators, inserts of quick connector and an electrical connector for easy connection to an electronic system, such as a rack mounted, server system.

FIG. 3C depicts a partial view of a rack mounted system housing with a backplane for connection of a plurality of boards such as those in FIGS. 3A and 3B.

### DETAILED DESCRIPTION

Whilst the making and using of various embodiments of the present invention are discussed in detail below, it should be appreciated that the present invention provides many applicable inventive concepts, which can be embodied in a wide variety of specific contexts. The specific embodiments discussed herein are merely illustrative of specific ways to make and use the invention and do not limit the scope of the invention.

It should be understood that the principles and applications disclosed herein can be applied in a wide range of data processing systems, telecommunication systems and other systems such as electrical and electronic systems. The present invention is particularly suited, but not limited to, rack mountable systems such as servers.

In the present invention, heat produced by a heat generating component, such as, but not limited to, a microprocessor in a data processing system, is transferred to a coolant in a heat transfer unit and dissipated in the cooling system. Liquid cooling solves performance and reliability problems associated with heating of various heat generating components in electronic systems.

The present invention may be utilized in a number of computing, communications, and personal convenience applications. For example, the present invention could be implemented in a variety of servers, workstations, exchanges, networks, controllers, digital switches, routers, personal computers which are portable or stationary, cell phones, and personal digital assistants (PDAs) and many others. As mentioned above, the present invention is particularly suited for rack mountable systems such as a server or the like, and one in which the number of heat-generating components requiring cooling operating may vary at any given time.

The present invention is equally applicable to a number of heat-generating components (e.g., central processing units, optical devices, data storage devices, digital signal processors or any component that generates significant heat in operation) within such systems. Furthermore, the dissipation of heat in this cooling system may be accomplished in any number of ways by a heat exchange unit of various designs, but which are not discussed in detail in this application. While the depicted example illustrates a system containing three heat transfer units, and one heat exchanger, it is within the scope of this invention to have any number of heat exchangers, and any number of heat transfer units.

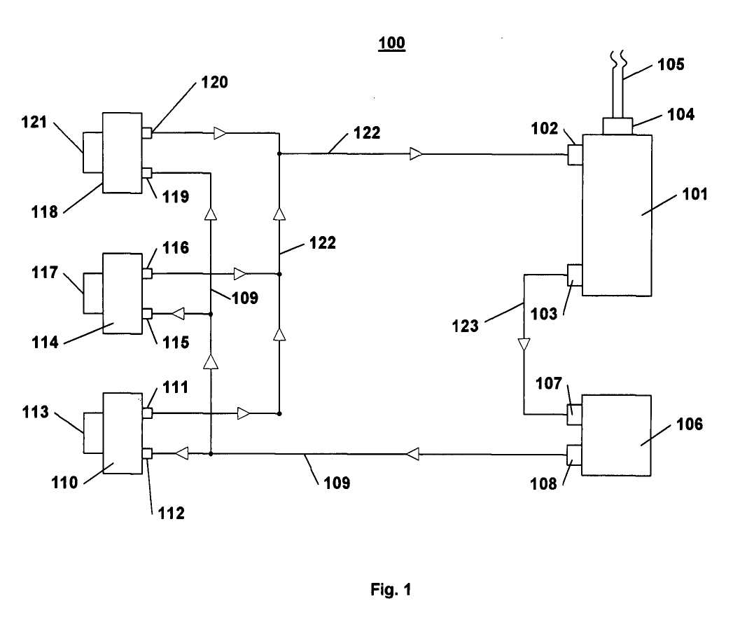

Referring now to FIG. 1, a schematic diagram of a cooling system 100 is depicted. A plurality of heat transfer units 110, 114 and 118 are depicted. Heat transfer unit 110 has an inlet 112 for receiving cooled coolant and an outlet 111 for disbursing heated coolant. Heat transfer unit 110 is thermally coupled to a heat generating component 113 such as, but not limited to, a microprocessor.

Similarly, heat transfer unit 114 has an inlet 115 for receiving cooled coolant and an outlet 116 for disbursing heated coolant. Heat transfer unit 114 is thermally coupled to a heat generating component 117 such as, but not limited to, a microprocessor. Heat transfer unit 118 has an inlet 119 for receiving cooled coolant and an outlet 120 for disbursing heated coolant. Heat transfer unit 118 is thermally coupled to a heat generating component 121 such as, but not limited to, a microprocessor.

Heat exchange unit 101 has an inlet 102 to receive heated coolant, and outlet 103 to provide cooled coolant, a motor 104 to operate a pump (not shown) and electrical wires 105 to provide the motor 104 with electrical power. Coolant regulator 106 is depicted with an inlet 107 and an outlet 108. Conduit 122 connects the inlet 102 of the heat exchange unit 101 to the outlets 120, 116 and 111 of heat transfer units 118, 114 and 110, respectively. Conduit 109 connects the outlet 108 of coolant regulator 106 to inlets 112, 115, and 119 of heat transfer units 110, 114 and 118, respectively. Conduit 123 connects the outlet 103 of heat exchange unit 101 to the inlet 107 of coolant regulator 106.

In operation, heat transfer units 110, 114 and 118 receive cooled coolant at their respective inlets 112, 115 and 119 through conduit 109. As the cooled coolant circulates through the heat transfer units 110, 114 and 118 heat is absorbed into the coolant from the heat generating components 113, 117 and 121, respectively, cooling the heat generating components and creating heated coolant. The heated coolant is then directed out of the heat transfer units 110, 114 and 118 through outlets 111, 116 and 120, respectively, and into conduit 122 to inlet 102 of heat exchange unit 101 where it is cooled by heat exchange unit 101. Cooled coolant is directed from the outlet 103 of heat exchange unit 101 to the inlet 107 of coolant regulator 106 through conduit 123. The cooled coolant is then directed back to the heat transfer units 110, 114 and 118 via conduit 109.

The coolant regulator 106 maintains a consistent pressure and/or volume of coolant for the cooling system 100. It is particularly useful for systems, such as, but not limited to, servers and other rack mounted systems where the number of heat transfer units connected to the system may be added to or subtracted from at any time while the electronic system remains operational. As additional heat transfer units are added or subtracted, the coolant pressure and/or volume will decrease or increase, respectively. The coolant regulator senses the changes in pressure and/or volume and automatically adjusts the pressure and/or volume of the coolant back to the desired level.

It will be appreciated that the coolant regulator 106 may be disposed in many different places in the cooling system 100. Moreover, a plurality of coolant regulators may used in any cooling system as well.

It will be appreciated that all of the embodiments of the present invention encompass the use of any form or type of heat transfer unit or the combination of different types of heat transfer units. However, a connector or socket heat transfer unit as described in U.S. patent application Ser. No. 11/319,942 filed Dec. 29, 2005 is preferable. This form of heat transfer unit can be used with one or more heat generating components and can be soldered or otherwise affixed to the motherboard 101 before the heat generating components are inserted. It further provides the advantage of easy assembly since the heat transfer units are already in place before the heat generating components are inserted into the socket connector.

It will be further understood that, in all of the embodiments of the present invention, any number and type of heat exchange units may be employed including heat exchange units with or without reservoirs; with or without a pump; and with or without fans or other air flow devices. It should also be appreciated that a remotely mounted or external heat exchange unit may also be used. The heat exchange unit may be used to cool one or more heat transfer units connected in series or parallel or any combination thereof.

Any number of coolants, liquid or gas, may be used with any of embodiments of the present invention such as, for example, a propylene-glycol based coolant. The scope of this invention also includes refrigerated cooling systems of all types including, but not limited to, systems utilizing both conventional Freon based systems and/or solid state cooling systems.

Whenever possible, it is desirable to orient any or all of the heat transfer units, such as heat transfer units 110, 114 and 118, in the system so that cooled coolant is received at a point below where heated coolant exits the heat transfer unit. This orientation allows the cooling system to take advantage of convective circulation of the coolant since heated coolant will naturally rise and cooled coolant will naturally drop. In this manner, the convective flow of the coolant can assist forced circulation, by a pump for example, and provide additional cooling of the heat generating components even after power is shut down to the electronic system through convective circulation. Similarly, and for the same reasons, it is desirable to orient any heat exchange units, such as heat exchange unit 101, in the system so that heated coolant is received at a point above where cooled coolant exits the heat exchange unit.

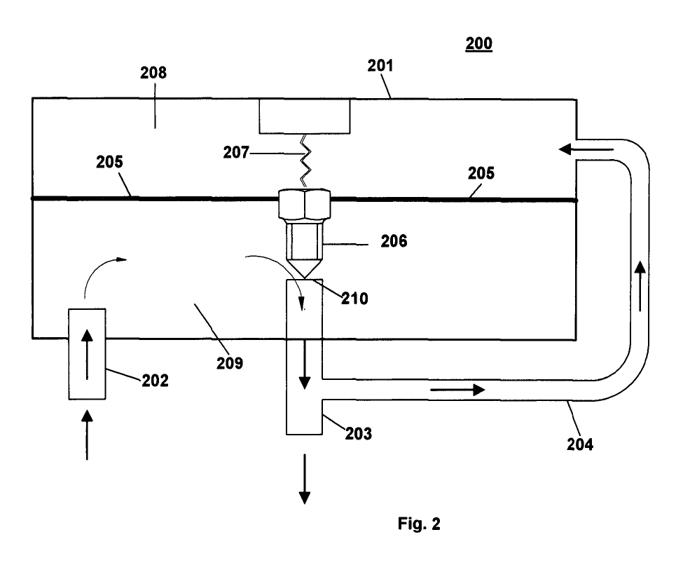

Referring now to FIG. 2, a coolant regulator 200 is depicted. Coolant enters the lower portion 209 of the housing 201 of the coolant regulator 200 through inlet 202 and exits the coolant regulator 200 through outlet 203. Pressure from the coolant exiting the coolant regulator 200 is directed from the outlet 203 through conduit 204 to an upper portion 208 of the housing 201. A flexible diaphragm 205 separates the upper portion 208 of the housing 201 from the lower portion 209 of the housing 201. Coupled to the diaphragm 205 is a plunger 206 acting as a flow regulator. The plunger 206 regulates pressure and/or volume by opening or restricting the opening 210 of outlet 203. This is accomplished by a spring 207 or other retention mechanism to move plunger 206 away from the opening 210 of conduit 203. When increased pressure is applied to the inlet 202, the pressure increases out of outlet 203. Part of this increased pressure is introduced to conduit 204 which, in turn, pressurizes the upper portion 208 of the housing 201. This, in turn, applies pressure to diaphragm 205. When the pressure reaches a predetermined threshold, the plunger 206 moves closer to the opening 210 of outlet 203. If the pressure rises above pre calibrated levels the volume allowed to exit 203 is restricted. This restriction regulates output pressure and/or volume of the coolant exiting outlet 203.

The tension of the spring 207 and the sensitivity of the diaphragm 205 are pre-set to maintain the desired level of coolant pressure and/or volume. It is within the scope of this invention to include a means to vary the tension on the spring 207 thus making the regulator adjustable. This means to vary the tension would make the regulator output pressure and/or volume adjustable.

In operation (in a rack mounted server system, for example) as circuit boards or cards with heat generating components with heat transfer units thermally coupled there to are added, on-line, to the system, the increased requirement for volume of coolant in the cooling system will cause the coolant pressure to drop. As a result, the pressure on diaphragm 205 in chamber 208 will decrease. As a result of decreased pressure, spring 207 will pull plunger 206 away from the opening 210 of outlet 203. This action allows more coolant to exit outlet 203 which increases coolant volume and/or pressure. This action is performed automatically and delivers coolant volume and/or pressure at the desired level to maintain consistent coolant flow to and through the heat transfer units.

Conversely, if one or more circuit boards with heat generating components and heat transfer units are removed from the system on-line, there will be a resulting increase in coolant pressure from the decreased requirement for coolant volume in the cooling system. This will cause the pressure of the coolant entering the upper portion 208 of the housing 201 to increase which, in turn, will force diaphragm 205 and plunger 206 downward. This, in turn, restricts the opening 210 of the outlet 203. This action rapidly regulates the coolant pressure in the cooling system automatically stabilizing pressures to the desired level. In turn, the volume of coolant to and through the heat transfer units, thermally coupled to the heat generating components is maintained at a consistent level.

When the system is shut down, the plunger or flow regulator 206 opens to the point of least restriction. This facilitates convective coolant flow or circulation after system shutdown.

It will be appreciated that a variety of mechanisms for regulating the coolant pressure and/or volume may be used and remain with the purview of the present invention. The depiction 200 illustrates one method of regulation.

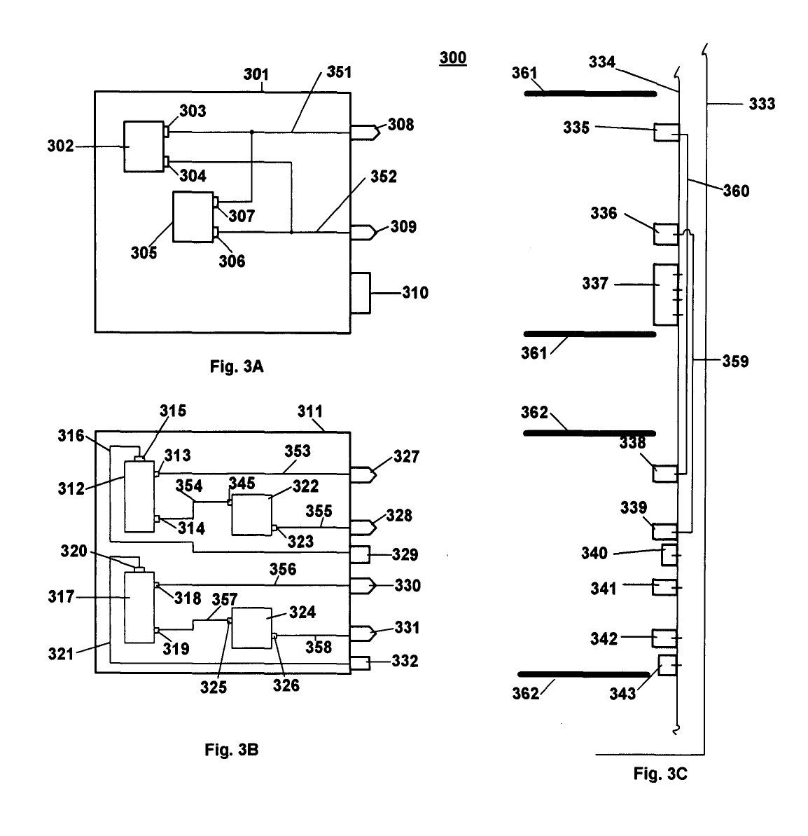

In FIGS. 3A, 3B and 3C, the present invention is depicted in use in a rack mountable system such as a server where circuit boards are being added to and subtracted from the system on line. Reference is made here to pending U.S. application Ser. No. 11/361,943 for a more detailed explanation of quick connectors and slide guides for connecting the cooling transport system and the circuit boards to electronic systems.

In FIG. 3A, a circuit board 301 which plugs into a rack mountable system 300 is depicted. The circuit board 301 is populated with many components, most of which are not shown. An electrical connector 310 is disposed on an edge of the board 301 for enabling electrical connection of the card 301 to the electronic system 300 when inserted into receptacle 337. Heat transfer units 302 and 305 are disposed on the board 301 and each is thermally coupled to one or more heat generating components (not shown) such as microprocessors. Cooled coolant is received at the inlets 304 and 306 of the heat transfer units 302 and 305, respectively, through conduit 352. The coolant is heated in the heat transfer units 302 and 305 by the transfer of heat from the heat generating components to the coolant and the heated coolant exits the outlets 303 and 307 of the heat transfer units 302 and 305, respectively, into conduit 351.

The conduits 351 and 352 are terminated with quick connector inserts 308 and 309, respectively. Conduits 351 and 352 are preferably coupled to the edge of board 301 such that their positioning remains fixed and so that, when the card 301 is inserted into the electronic system 300, the quick connector inserts 308 and 309 automatically align with and connect to their corresponding receptacles, 335 and 336, respectively, of the quick connectors shown in FIG. 3C. However, the conduits 351 and 352 may also be free-standing or connected in a harness.

The inserts 308 and 309 may include an automatic sealing mechanism such that, when not connected to their mating receptacles, 335 and 336, respectively, a seal is formed preventing any coolant from escaping from the heat transfer units 302 and 305 or conduits 351 and 352. Use of such a sealing mechanism allows for the disposition of coolant in the heat transfer units 302 and 305 and in conduits 351 and 352 before connection to the system 300. It also prevents excessive leaks or spills of coolant when the card 301 is disconnected from the system 300.

Board 301 is designed to be inserted into slide guides 361 for connection to the backplane 334 of the system 300. When the board 301 is fully inserted into the slide guides 361, all electrical and cooling system connections are made automatically. It will be appreciated that a typical system 300, such as a rack mountable server, for example, will have a plurality of such boards 301 normally connected to the system 300. Moreover, boards may be and often are added to the system 300 or removed from the system 300, on line. It will be further appreciated that each board 301 may have any number of heat transfer units, such as heat transfer units 302 and 305, disposed thereon. The heat transfer units may be connected to the conduits 351 and 352 in parallel, in series, or in any combination thereof.

FIG. 3B depicts a interconnection device or board 311 for rack mounting into the system 300 and having heat exchange units 312 and 317 as well as coolant regulators 322 and 324 disposed thereon. The board 311 may be made of any suitable rigid material, such as, but not limited to, metal, for example, and should be designed to be inserted into slide guides 362 for connection to the system 300.

Heat exchange unit 312 has an inlet 313 for receiving heated coolant via conduit 353 and the insert 327 of a quick connector. The heat exchange unit 312 dissipates heat from the heated coolant and provides cooled coolant at its outlet 314. The outlet 314 of heat exchange unit 312 is connected to the inlet 345 of coolant regulator 322 via conduit 354. The outlet 323 of coolant regulator 322 is connected to the insert 328 of a quick connector via conduit 355. Heat exchange unit 312 is also depicted with a motor 315 for operating a pump (not shown). The motor 315 is electrically connected to connector 329 by wires 316.

Heat exchange unit 317 has an inlet 318 for receiving heated coolant via conduit 356 and the insert 330 of a quick connector. The heat exchange unit 317 dissipates heat from the heated coolant and provides cooled coolant at its outlet 319. The outlet 319 of heat exchange unit 317 is connected to the inlet 325 of coolant regulator 324 via conduit 357. The outlet 326 of coolant regulator 324 is connected to the insert 331 of a quick connector via conduit 358. Heat exchange unit 317 is also depicted with a motor 320 for operating a pump (not shown). The motor 320 is electrically connected to connector 332 by wires 321.

It will be appreciated that a system 300 may require more than one board 311. Moreover, each board 311 may have one or more heat exchange units disposed thereon and that the heat exchange units may operate singly or be connected in series to cool the coolant. It shall be further appreciated that the heat exchange units and the coolant regulators may be disposed on different boards for separate connection to and from system 300. It shall be still further appreciated that either or both of the heat exchange units and the coolant regulators may be disposed elsewhere in the system, in lieu of board 311, such as for example, the system housing 333 or backplane 334 of FIG. 3C.

The quick connector inserts 327, 328, 330 and 331 may include an automatic sealing mechanism such that, when not connected to their mating receptacles, 338, 339, 341 and 342, respectively, a seal is formed preventing any coolant from escaping from the heat exchange units 312 and 317, the coolant regulators 322 and 324 or conduits 353, 354, 355, 356, 357 and 358. Use of such a sealing mechanism allows for the disposition of coolant in the heat exchange units 312 and 317, coolant regulators 322 and 324 and in conduits 353, 354, 355, 356, 357 and 358 before connection to the system 300. It also prevents excessive leaks or spills of coolant when the board 311 is disconnected from the system 300.

FIG. 3C depicts a partial schematic view of the system housing 333 and the system backplane 334. Boards 301 and 311 in FIGS. 3A and 3B, respectively, are inserted in to slide guides 361 and 362, respectively, in the housing 333 for connection to the backplane 334 of the system 300.

Backplane 334 is affixed to the inside of the system housing 333 and has disposed thereon receptacles for receiving inserts and connectors from boards 301 and 311. More specifically, quick connector receptacles 335 and 336 are disposed on backplane 334 such that they mate with quick connector inserts 308 and 309, respectively, on board 301 when card 301 is fully inserted into the housing 333. Additionally, electrical receptacle 337, disposed on the backplane 334, also mates with electrical connector 310 on board 301 when board 301 is fully inserted into the housing 333.

Receptacle 335 is coupled to receptacle 338 disposed on backplane 334 by a conduit 360 for transporting coolant between these two receptacles. Similarly, receptacle 336 is coupled to receptacle 339 disposed on backplane 334 by a conduit 359 for transporting coolant between these two receptacles. Depending on the particular system 300 requirements, receptacle 338 may also be connected to additional quick connect receptacles (not shown) similar to receptacle 335 that mate with quick connector inserts similar to quick connector insert 308 for other boards similar to board 301 and receptacle 339 may also be connected to additional quick connect receptacles (not shown) similar to receptacle 336 that mate with quick connector inserts similar to quick connector insert 309 for other boards similar to board 301.

Conduits 359 and 360 may be free standing or secured separately to backplane 344 or housing 333 or coupled together and/or with other conduits as part of one or more harnesses for completing the coolant transport system for system 300.

Quick connector receptacles 338 and 339 are disposed on backplane 334 such that they mate with quick connector inserts 327 and 328, respectively, on board 311 when board 311 is fully inserted into the housing 333. Additionally, electrical receptacle 340, disposed on the backplane 334, also mates with electrical connector 329 on board 311 when board 311 is fully inserted into the housing 333. Quick connector receptacles 341 and 342 are disposed on backplane 334 such that they mate with quick connector inserts 330 and 331, respectively, on board 311 when board 311 is fully inserted into the housing 333. Additionally, electrical receptacle 343, disposed on the backplane 334, also mates with electrical connector 332 on board 311 when board 311 is fully inserted into the housing 333. Receptacles 341 and 342 would be coupled by conduits (not shown) to other receptacles (not shown) disposed on the backplane 334 for mating with quick connector inserts (not shown) similar to inserts 335 and 336, respectively, of other boards (not shown) similar to board 301.

Backplane 334 would thus be equipped with a plurality quick connector receptacles and electrical receptacles to accept a plurality of boards similar to board 301 and one or more boards similar to board 311. In operation, boards similar to board 301 may be added to or removed from the system 300 at any time while the entire system 300 remains on line.

The receptacles 335, 336, 338, 339, 341 and 342 may include an automatic sealing mechanism such that, when not connected to their mating inserts, 308, 309, 327, 328, 330 and 331, respectively, a seal is formed preventing any coolant from escaping from the conduits 359 and 360. Use of such a sealing mechanism allows for the disposition of coolant in the conduits 359 and 360 before connection to the system 300. It also prevents excessive leaks or spills of coolant when a board, such as board 301 or board 311 is disconnected from the system 300.

When boards 301 and 311 are fully inserted into the system 300, quick connector inserts 308, 309, 327, 328, 330 and 331 mate and lock with quick connector receptacles 335, 336, 338, 339, 341 and 342, respectively. This establishes coolant communication between the heat exchange unit and coolant regulator and corresponding heat transfer units. With respect to FIGS. 3A and 3B then, the outlets 303 and 307 of heat transfer units 302 and 305, respectively, are connected to the inlet 313 of heat exchange unit 312 such that heated coolant can be transferred to the heat exchange unit 312. Similarly, the inlets 304 and 306 of heat transfer units 302 and 305, respectively, are connected to the outlet 323 of coolant regulator 322 such that cooled coolant is transferred to heat transfer units 302 and 305.

It will be further understood that, in all embodiments of the present invention, the quick connectors may also be arranged so that the insert portions are disposed on backplane 334 and the receptacle portions are disposed on boards 301 and 311. Additionally, other combinations may also be used such as, for example, a quick connector insert 308 and a quick connector receptacle 309 mating with a quick connector receptacle 335 and a quick connector insert 336, respectively.

When boards 301 and 311 are fully inserted into the system 300, electrical connector 310 is mated with electrical receptacle 337 thereby furnishing board 301 with electrical power and electrical connector 329 is mated with electrical receptacle 340 thereby furnishing the motor 315 of heat exchange unit 312 with electrical power.

A similar set of connections occurs when board 311 is fully inserted into the system 300 for heat exchange unit 317 and coolant regulator 324. The inlet 318 of heat exchange unit 317 would be connected to the outlets similar to outlets 303 and 307 of heat transfer units disposed on other boards similar to board 301. The outlet of coolant regulator 324 would be connected to the inlets, similar to inlets 304 and 306 of heat transfer units on these other boards similar to board 301.

In this manner, a large system such as, but not limited to, a rack mountable server can be configured so that boards similar to board 301 may be inserted into or removed from the system while the system is on-line and automatic connection to and from the cooling system(s) occurs while the coolant pressure and/or volume is maintained at a consistent level.

Finally, the backplane 334 and the electrical connectors and receptacles can be easily configured to conserve electrical power and extend the lifetime of heat exchange unit motors and pumps similar to motor 315 when there are no boards similar to board 301 connected to the system 300 requiring cooling from heat exchange unit 312, for example. One such method of configuring the system for such power and lifetime conservation is to wire two pins in connector 310 together for all boards similar to board 301. The wiring of all electrical receptacles 337 for the pins to be coupled to the wired together pins of the connectors 310 for all boards 301 which will be coupled to heat exchange unit 312 would then form a series of switches in parallel with electrical receptacle 341. As would be obvious to anyone skilled in the art, this configuration would provide motor 315 with electrical power whenever any one or more boards 301 to be cooled by heat exchange unit 312 are connected to the system. Conversely, if no board 301, to be cooled by heat exchange unit 312, is connected to the system 300, then no power would be provided to motor 315 thus conserving power and extending the lifetime of heat exchange unit 312.

Thus, the present invention has been described herein with reference to particular embodiments for particular applications. Those having ordinary skill in the art and access to the present teachings will recognize additional modifications, applications, and embodiments within the scope thereof.

It is, therefore, intended by the appended claims to cover any and all such applications, modifications, and embodiments within the scope of the present invention.

What is claimed is:

1. A cooling system having a coolant for cooling one or more heat-generating components in an electronic system comprising:
one or more heat transfer units thermally coupled to one or more heat-generating components and having the coolant circulating there through for transferring heat from the heat-generating components to the coolant; and
one or more coolant regulators wherein the regulator maintains consistent coolant pressure and/or volume of coolant to the heat transfer units regardless of how many heat-generating components are connected to the electronic system.

2. The cooling system as set forth in claim 1 wherein the coolant regulators maintain consistent coolant pressure and/or volume before and after heat-generating components are added to or removed from the electronic system.

3. The cooling system as set forth in claim 1 further comprising:
one or more heat exchange units for receiving heated coolant at an inlet and for cooling said coolant to provide cooled coolant at an outlet;
a variable number of heat transfer units thermally coupled to the one or more heat-generating components, the heat transfer units receiving cooled coolant at an inlet there of from a heat exchange unit, transferring heat to the cooled coolant from one or more heat-generating components thermally coupled thereto and creating heated coolant and directing the heated coolant from an outlet thereof to a heat exchange unit for cooling the heated coolant;
one or more transport means coupled to the heat transfer units and the heat exchange units for transporting cooled coolant from the heat exchange units to the heat transfer units and for transporting heated coolant from the heat transfer units to the heat exchange units; and
wherein the coolant regulators are coupled to the transport means.

4. The cooling system as set forth in claim 3 wherein one or more heat transfer units have an inlet positioned below an outlet for enhancing convective circulation of the coolant.

5. The cooling system as set forth in claim 3 wherein one or more heat exchange units have an inlet positioned above an outlet for enhancing convective circulation of the coolant.

6. The cooling system as set forth in claim 1 wherein the one or more coolant regulators are configured to allow maximum coolant volume to flow in the cooling system when power to the electronic system is disabled thereby enhancing convective circulation of the coolant after power shutdown.

7. The cooling system as set forth in claim 3 wherein one or more heat transfer units are disposed on an interconnect means, said interconnect means further comprising:
one or more inserts or receptacles of one or more quick connectors and disposed such that one or more inserts or receptacles engage with a mating receptacle or insert, respectively, when the interconnect means is connected to the electronic system thereby enabling coolant communication to the heat transfer units and disengage when the interconnect means is disconnected from the electronic system thereby disabling coolant communication to the heat transfer units;
heat transfer unit transport means for coupling the inlets and the outlets of the heat transfer units to the inserts or receptacles disposed on the interconnect means, and
guide means coupled to the housing of the electronic system for insertion of the interconnect means there in for connecting and disconnecting the interconnect means to and from the electronic system.

8. The cooling system as set forth in claim 7 wherein the interconnect means is a circuit board.

9. The cooling system as set forth in claim 7 further comprising one or more electrical connectors or receptacles disposed on the interconnect means for connecting with a mating receptacle or connector coupled for enabling electrical power to the interconnect means when the interconnect means circuit card is connected to the electronic system and disabling electrical power when the interconnect means is disconnected from the electronic system.

10. The cooling system as set forth in claim 9 further comprising:
sensing means coupled to the interconnect means for enabling electrical power to one or more heat exchange units when an interconnect means is connected to the electronic system.

11. The cooling system as set forth in claim 3 wherein one or more heat exchange units are disposed on an interconnect means, said interconnect means further comprising:
one or more inserts or receptacles of one or more quick connectors and disposed such that one or more inserts or receptacles engage with a mating receptacle or insert, respectively, when the interconnect means is connected to the electronic system thereby enabling coolant communication to the heat exchange units and disengage when the interconnect means is disconnected from the electronic system thereby disabling coolant communication to the heat exchange units;
heat exchange unit transport means for coupling the inlets and the outlets of the heat exchange units to the inserts or receptacles disposed on the interconnect means; and
guide means coupled to the housing of the electronic system for insertion of the interconnect means there in for connecting and disconnecting the interconnect means to and from the cooling system.

12. The cooling system as set forth in claim 11 further comprising one or more electrical connectors or receptacles disposed on the interconnect means for connecting with a mating receptacle or connector for enabling electrical power to the heat exchange units when the interconnect means is connected to the electronic system and disabling electrical power when the interconnect means is disconnected from the electronic system.

13. The cooling system as set forth in claim 12 further comprising:
sensing means coupled to the electrical connectors or receptacles and responsive to the presence of one or more heat transfer units in coolant communication with one or more heat exchange units for enabling electrical power to such heat exchange units when one or more heat transfer units are in coolant communication with such heat exchange units and disabling electrical power to such heat exchange unit when no heat transfer units are in coolant communication with such heat exchange units.

14. The cooling system as set forth in claim 11 wherein one or more coolant regulators are disposed on the interconnect means and coupled to one or more heat exchange units.

15. The cooling system as set forth in claim 3 wherein one or more coolant regulators are disposed on an interconnect means, said interconnect means further comprising:
one or more inserts or receptacles of one or more quick connectors and disposed such that one or more inserts or receptacles engage with a mating receptacle or insert, respectively, when the interconnect means is connected to the electronic system thereby enabling coolant communication to the coolant regulators and disengage when the interconnect means is disconnected from the electronic system thereby disabling coolant communication to the coolant regulators;
coolant regulator transport means for coupling the inlets and the outlets of the heat transfer units to the inserts or receptacles disposed on the interconnect means; and
guide means coupled to the housing of the electronic system for insertion of the interconnect means there in for connecting and disconnecting the interconnect means to and from the cooling system.

16. The cooling system as set forth in claim 1 wherein the coolant regulator comprises;
a housing having a coolant inlet and a coolant outlet;
a movable pressure and/or volume sensing means responsive to the pressure and/or volume of the coolant;
a flow control means coupled to the movable pressure sensing means for increasing or decreasing the pressure and/or volume of coolant; and
coolant return means for transporting some of the coolant flowing through the coolant regulator back to the housing such that the movable pressure sensing means responds to increases in coolant pressure and/or volume.

17. The cooling system as set forth in claim 16 wherein the movable pressure and/or volume sensing means is adjusted to maintain a relatively constant coolant pressure and/or volume of coolant to the heat transfer units.

18. A server having the cooling system of claim 1.

19. A device having one or more heat-generating components and having the cooling system of claim 1.

20. A method of cooling a variable number of heat transfer units thermally coupled to one or more heat-generating components in an electronic system, the heat transfer units for transferring heat from the heat-generating components to a coolant circulating through the heat transfer units, the method comprising the step of:
regulating the coolant pressure and/or volume of coolant to the heat transfer units such that, when additional heat transfer units are connected to the system, the coolant pressure and/or volume of coolant to the heat transfer units are/is maintained at a consistent level irrespective of the number of heat transfer units connected to the system.
